(19) United States
(12) Patent Application Publication
(10) Pub. No.: US 2007/0069296 A1
(43) Pub. Date: Mar. 29, 2007

(54) High-density high current device cell

(76) Inventors: Human Park, Paris (FR); Rainer Leuschner, Samoreau (FR); Ulrich Klostermann, Fontainebleau (FR); Richard Ferrant, Esquibien (FR)

Correspondence Address: SLATER & MATSIL LLP, 17950 PRESTON ROAD, SUITE 1000, DALLAS, TX, 75252, US

(21) Appl. No.: 11/369,194

(22) Filed: Mar. 6, 2006

(30) Foreign Application Priority Data
Sep. 29, 2005 (DE) 10 2005 046 777.6

(51) Int. Cl. H01L 27/12

(52) U.S. Cl. 257/351; 257/E29.255

(57) ABSTRACT

A cell design and methods for reducing the cell size of cells in high-current devices, such as MRAM, by increasing the effective width of a transistor in the cell to be greater than the actual width of the active area of the cell are described. This permits the cell size to be decreased without decreasing the current that is driven by the transistor. According to the invention, this is achieved by increasing the length of gate portions of one or more transistors within the active area of a cell to increase the effective transistor width. In one embodiment, two transistors, electrically connected in parallel, are used per cell. The two transistors double the effective transistor width within the cell relative to a single transistor design. Such cell designs can be used with a variety of devices, including various types of MRAM and PCRAM.

This application claims priority to German Patent Application 10 2005 046 777.6, which was filed Sep. 29, 2005, and is incorporated herein by reference.

### TECHNICAL FIELD

The present invention relates generally to semiconductor devices having multiple cells, such as MRAM (Magneto-resistive Random Access Memory) devices, and more particularly to the design of cells in such devices that are able to drive a relatively high current for the size of the cell.

### BACKGROUND

One emerging technology for non-volatile memory is magneto-resistive random access memory (MRAM). A common form of MRAM is based on the tunnelling magneto-resistance (TMR) effect, in which each memory cell comprises a magnetic tunnel junction (MTJ). Such an MTJ may be formed from two ferromagnetic metal layers, with an insulating, or “barrier” layer placed between the metal layers. When a voltage is applied between the metal layers, a tunnel current flows. The tunnel resistance varies based on the relative directions of magnetization of the metal layers. The tunnel resistance is small when the directions of magnetization are parallel (typically representing a “0”), and large (approximately 10%-20% higher, at room temperature) when the directions of magnetization are anti-parallel (typically representing a “1”).

The metal layers in a typical MRAM MTJ include a “fixed” layer, in which the direction of the magnetization is fixed, and a “free” layer, in which the direction of the magnetization can be switched by application of currents. These currents are typically applied through conductive write lines referred to as bit lines and word lines, which are disposed so that the bit lines are orthogonal to the word lines. In an MRAM array, an MTJ memory cell is located at each intersection of a bit line with a word line.

In a typical MTJ cell, to switch the direction of magnetization of the free layer of a particular cell, currents are applied through the bit line and the word line that intersect at that cell. The direction of these currents determines the direction in which the magnetization of the free layer will be set. The combined magnitude of the currents through the word and bit lines must be sufficient to generate a magnetic field at their intersection that is strong enough to switch the direction of magnetization of the free layer.

One difficulty with such MRAM designs is that, because a magnetic field is used to write the cells, there is a risk of inadvertently switching memory cells that are adjacent to the targeted memory cell, due, for example, to inconsistencies in the magnetic material properties of the cells. Additionally, any memory cells located along the same word or bit line as the selected cell are subject to a portion of the magnetic switching field, and may be inadvertently switched. Other causes of undesired switching of cells may, for example, include fluctuations in the magnetic field, or alterations in the shape of the field.

In MRAM designs known as thermal select MRAMS, these difficulties are addressed by thermal heating. A heating current is applied to reduce the saturation magnetization for the selected cells. Using this method, only the heated cells can be switched, reducing the occurrence of inadvertent cell switching. In some designs, this heating may be achieved by passing a current through the barrier layer of a cell, the resistance of which heats the cell.

Another type of MRAM that addresses these difficulties uses current-induced spin transfer to switch the free layer of the MTJ. In such “spin-injection” MRAM, the free layer is not switched via application of a magnetic field generated by the bit lines and word lines. Instead, a write current is forced directly through the MTJ to switch the free layer. The direction of the write current through the MTJ determines whether the MTJ is switched into a “0” state or a “1” state. A select transistor connected in series with the MTJ may be used to select a particular cell for a write operation.

Another difficulty that is encountered in MRAM is the size of the cells. In the current highly competitive market for memory devices, it is necessary to achieve high density by minimization of cell size. Unfortunately, in many MRAM designs, it is very difficult to reduce the cell size to compete with other types of memory devices. This has several causes. First, MRAM cells generally require a drastically higher write current than conventional DRAM (Dynamic Random Access Memory), particularly when thermal select MRAM or spin injection MRAM is being used. Since the write current is limited by the transistor dimensions in a cell, the transistor dimensions may need to be relatively large in MRAM devices. Additionally, features such as the size of the individual ground contacts and via connections to a metal line for each memory cell are a large contributor to the size of cells in many MRAM designs.

Similar difficulties with cell size are encountered in other recent memory technologies, such as phase-change random access memories (PCRAM), in which data are written by using ohmic heating to change the phase of a material between an amorphous and a crystalline state. The heating operation in such PCRAM requires a relatively high write current, leading to difficulties similar to those encountered with MRAM.

What is needed in the art is a design for cells for high-write current memory technologies, such as MRAM, with reduced cell size.

### SUMMARY OF THE INVENTION

Embodiments of the present invention provide a way of reducing the cell size for cells in high-current devices, such as MRAM, by increasing the effective width of a transistor in the cell to be greater than the actual width of the active area of the cell. This permits the cell size to be decreased without decreasing the current that is driven by the transistor. This is achieved by increasing the width of gate portions of one or more transistors within the active area of a cell to increase the effective transistor width.

In one embodiment, two transistors, electrically connected in parallel, are used per cell. The two transistors double the effective transistor width within the cell relative to a single transistor design. This permits the width of the cell to be decreased while the effective transistor width in the cell, and the ability of the cell to drive a current, are maintained or increased.

This two-transistor design also permits the sidewall spacers of the gates of the transistors to be used for self-alignment of a via connection from a magnetic tunnel junction or other device to the transistors, reducing the area required for this via connection. Additionally, the symmetry of this two-transistor design permits the drain regions of the transistors to be shared with transistors in adjacent cells. The sidewall spacers of the transistors in the cell and the transistors in adjacent cells are used for self-alignment of ground via connections to the drain regions, further decreasing cell size and, consequently, increasing cell density.

In an alternative embodiment, a single transistor design is used, in which the effective transistor width is increased by using a “zig-zag” pattern for the gate, thereby increasing the gate width within the active area of the cell. In this design, the gate includes at least three segments within the active area of the cell. Two of these segments are parallel to each other, and the third segment is perpendicular to the other two. The three segments have a total width that is greater than the width of the active area of the cell. Additionally, since the three segments. partially surround a via connection, they can be used for self-alignment of the via connection.

In accordance with embodiments of the invention, these cell designs can be advantageously used with a variety of devices, including various types of MRAM and PCRAM.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a perspective view of a prior art MRAM array;

FIGS. 2A and 2B show, respectively, a block diagram and a sample layout of a prior art thermal select MRAM cell;

FIG. 3 is a diagram of a circuit that models a thermal select MRAM cell for purposes of computing a cell width;

FIGS. 4A and 4B show, respectively, a block diagram and a sample layout of a two transistor thermal select MRAM cell in accordance with an embodiment of the present invention;

FIG. 5 shows a cross-section of a two transistor thermal select MRAM cell in accordance with an embodiment of the present invention; and

FIG. 6 shows a sample layout of a one transistor cell according to an alternative embodiment of the present invention.

### DETAILED DESCRIPTION OF ILLUSTRATIVE EMBODIMENTS

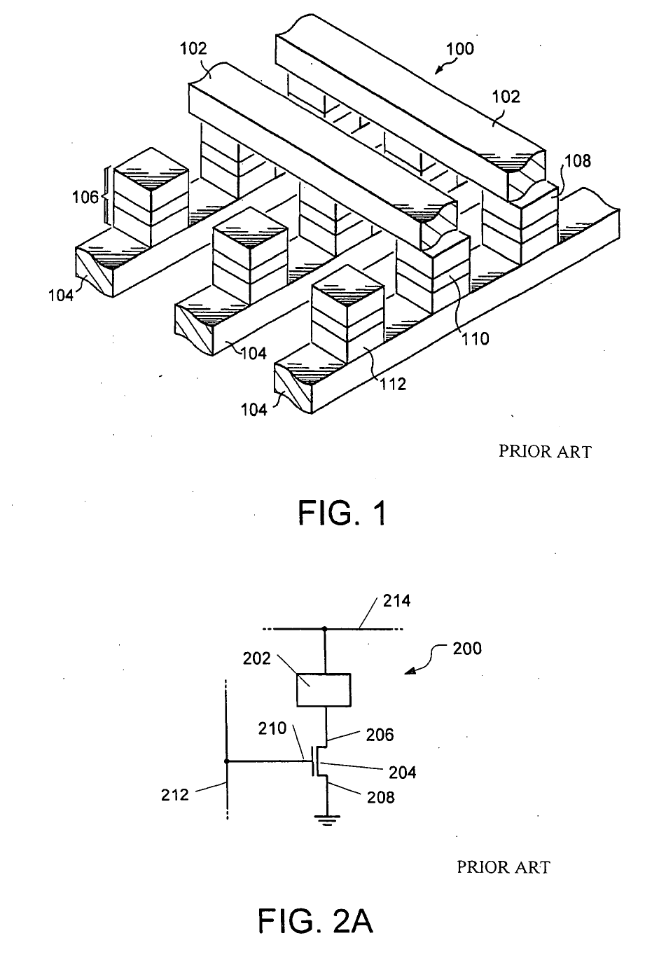

FIG. 1 shows a perspective view of a typical prior art MRAM array 100 having bit lines 102 disposed in an orthogonal direction to word lines 104 in adjacent metalization layers. Magnetic memory stacks 106 are electrically coupled to the bit lines 102 and word lines 104 (collectively, write lines), and are positioned between the bit lines 102 and word lines 104 at locations where a bit line 102 crosses a word line 104. The magnetic memory stacks 106 are preferably magnetic tunnel junctions (MTJs), comprising multiple layers, including a free layer 108, a tunnel layer 110, and a fixed layer 112. The free layer 108 and fixed layer 112 preferably comprise a plurality of magnetic metal layers (not shown). These magnetic metal layers may, for example, comprise eight to twelve layers of materials such as PtMn, CoFe, Ru, and NiFe. The tunnel layer 110 comprises a dielectric, such as Al₂O₃.

The fixed layer 112 is preferably magnetized in a fixed direction, while the direction of magnetization of the free layer 108 may be switched, changing the resistance of the magnetic memory stack 106. One bit of digital information may be stored in a magnetic memory stack 106 by running a current in the appropriate direction through the bit line 102 and the word line 104 that intersect at the magnetic memory stack 106, creating a sufficient magnetic field to set the direction of magnetization of the free layer 108. Information may be read from a magnetic memory stack 106 by applying a voltage across the magnetic memory stack, and measuring the resistance. If the direction of magnetization of the free layer 108 is parallel to the direction of magnetization of the fixed layer 112, then the measured resistance will be low, representing a value of “0” for the bit. If the direction of magnetization of the free layer 108 is anti-parallel to the direction of magnetization of the fixed layer 112, then the resistance will be high, representing a value of “1”.

It will be understood that the view shown in FIG. 1 is simplified, and that actual MRAM devices may include additional components. For example, in some MRAM designs, a transistor is coupled to each magnetic memory stack 106, for isolation. It will further be recognized that the view shown in FIG. 1 represents only a small portion of an actual MRAM device. Depending on the organization and memory capacity of the device, there may be hundreds or thousands of bit lines and word lines in a memory array. For example, a 1 Mb MRAM device (i.e., an MRAM device storing approximately one million bits of data) may include two arrays, each of which has 1024 word lines and 512 bit lines. Additionally, in some MRAM devices, there may be multiple layers of magnetic memory stacks, in which layers may share bit lines or word lines.

Variations in the MRAM technology in use may also lead to some variation in the basic design shown in FIG. 1. For example, in a typical thermal select MRAM, each cell includes a transistor (not shown) coupled between the MTJ and ground. The word line may be used to select the cell by being electrically connected to the gate of the transistor, so that a heating current flows through the cell from the bit line when the transistor is selected.

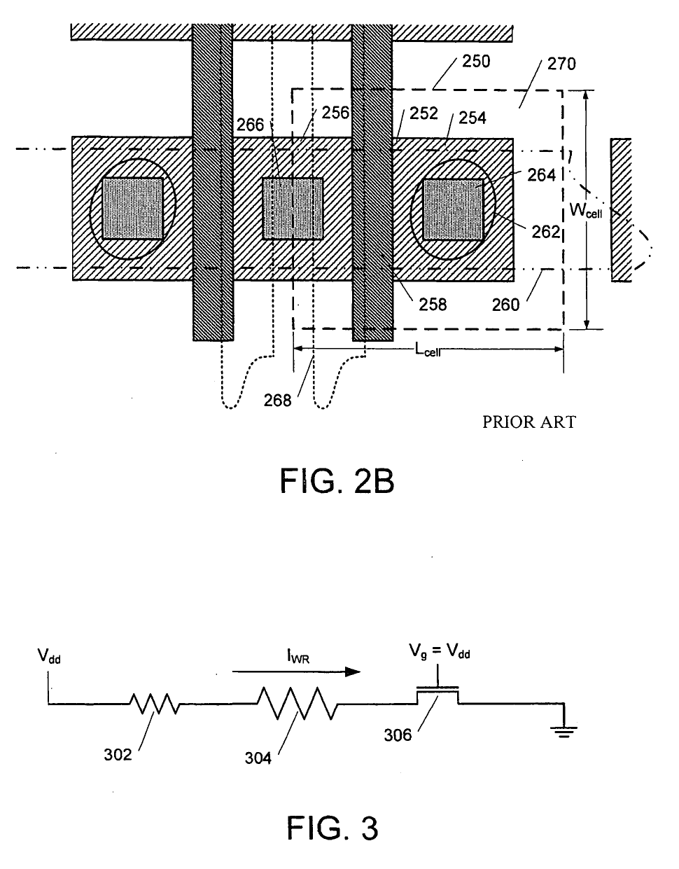

FIG. 2A shows a block diagram of a cell of a prior art thermal select MRAM device. A memory cell 200 includes a magnetic tunnel junction (MTJ) 202, electrically connected in series with a transistor 204. A source portion 206 of the transistor 204 is connected to the MTJ 202, a drain portion 208 of the transistor 204 is connected to ground, and a gate portion 210 of the transistor 204 is connected to a word line 212. A bit line 214 is electrically coupled to the MTJ 202. When the memory cell 200 is selected, a voltage on the word line 212 is applied to the gate portion 210 of the transistor 204, permitting current to flow from the bit line 214, through the MTJ 202 and the transistor 204. This current flow causes the heating of the MTJ 202, which permits a value to be written to the memory cell 200.

FIG. 2B shows an example layout for the prior art single transistor thermal select MRAM memory cell, such as is shown as a block diagram in FIG. 2A. For purposes of illustration, a 65 nm CMOS technology is used.

A memory cell 250 includes a transistor 252 having a source region 254, a drain region 256, and a gate 258. A bit line 260, in a metalization (M3) layer, is electrically connected to a magnetic tunnel junction (MTJ) 262, which is connected through a via connection 264 to the source region 254 of the transistor 252. The drain region 256 of the transistor 252 is electrically connected to a ground line (not shown) in a metalization (M1) layer (not shown) through a ground via connection 266. A word line 268 is electrically connected to the gate 258 of the transistor 252, so that a current may flow through the MTJ 262 and the transistor 252 when an activation voltage is applied on the word line 268. An isolation region 270 surrounds the transistor 252, electrically isolating the cell from other adjacent cells.

As can be seen in FIG. 2B, cell density is improved by sharing the drain region 256 and ground via connection 266 between the transistors of two adjacent cells. Thus, in measurements of the size of the memory cell 250, only half of the size of the drain region 256 and half of the size of the ground via connection 266 are included in the size of the cell 250.

In 65 nm CMOS technology, the overall width of the memory cell 250, W_{cell}, is approximately 300 nm. The length of the cell, L_{cell}, is approximately 325 nm. These sizes are determined by the minimum transistor width to handle the current necessary for writing to a thermal select MRAM cell, and by the size of the via contacts to the source region 254 and the drain region 256. In terms of the minimum feature size, F, of 65 nm, W_{cell} is 4.6 F, and L_{cell} is 5 F. This gives an overall cell area of 23 F².

To achieve a chip density that is competitive with other memory technologies, such as DRAM, it is necessary to reduce the size of the memory cell. For example, in 65 nm technology, an MRAM cell should be smaller than 10 F², to be competitive, where F is the minimum feature size (i.e., 65 nm). Therefore, it would be desirable to reduce the size of the cell by more than a factor of two.

Unfortunately, if the single-transistor design shown in FIGS. 2A and 2B is scaled down to a cell size of less than 10 F², it will be unable to meet the current requirements for a thermal select MRAM cell. For a thermal select MRAM cell, the current that is required to heat the magnetic Junction is determined by several factors, including the barrier resistance, the on-current of the transistor, and the transistor width. The maximum on-state current of an NFET in 65 nm CMOS technology is governed by the intrinsic transistor performance limit. To drive a high enough current for heating during the write operation, the cell must be wide enough to provide sufficient current.

FIG. 3 shows a model of a single transistor cell for use in estimating the required width of the transistor as a function of barrier resistance and write current. The bit line is modeled as a resistor 302, and the barrier resistance of the MTJ is modeled as a resistor 304. The transistor 306 is disposed between the resistor 304 and ground. A driver voltage, V_{dd}, is applied to cause a write current, I_{WR}, to flow through the system. For purposes of the model, the gate voltage of the transistor is also set at V_{dd}.

Assuming that the transistor is in saturation, then a first order approximation for the required transistor width is given by:

$${W}_{act} = ( \frac{{I}_{WR}}{{I}_{ON}} ) \frac{{V}_{dd}}{{V}_{dd} - {I}_{WR} ( {R}_{BL} + {R}_{Bar} )} \qquad ( 1 )$$

Where:

W_{act} is the width of the transistor;

I_{WR} is the write current;

I_{ON} is the on-current of the transistor;

V_{dd} is the driver voltage;

R_{BL} is the bit line resistance; and

R_{Bar} is the barrier resistance.

A reasonable target write voltage for a thermal select MRAM cell is approximately 65 μA. A typical barrier resistance for a magnetic junction comprising, for example, MgO, for use with a thermal select MRAM is approximately 3.5 KΩ. For this example, a value of 0.85V is used for V_{dd}, and 575 μA/μm for I_{ON}. Based on these values, the transistor width needs to be greater than 170 nm for a reasonably performing NFET in 65 nm technology to drive a high enough current.

If the one-transistor cell design shown in FIGS. 2A and 2B is scaled down be smaller than 10 F² in 65 nm technology, then the maximum transistor width will be approximately 130 nm. This is too small to drive the 65 μA write current.

In accordance with an embodiment of the present invention, these difficulties can be overcome through use of a design in which each cell includes two transistors electrically connected in parallel, with a common source region. This arrangement increases the effective transistor width, thereby permitting higher write current. Additionally, the two transistors in parallel provide a way for a via contact to be formed in a self-aligned manner, using the gate poly sidewall spacers. This self-aligned contact permits a reduction in cell size, since it is not necessary to provide extra space to allow for slight misalignments.

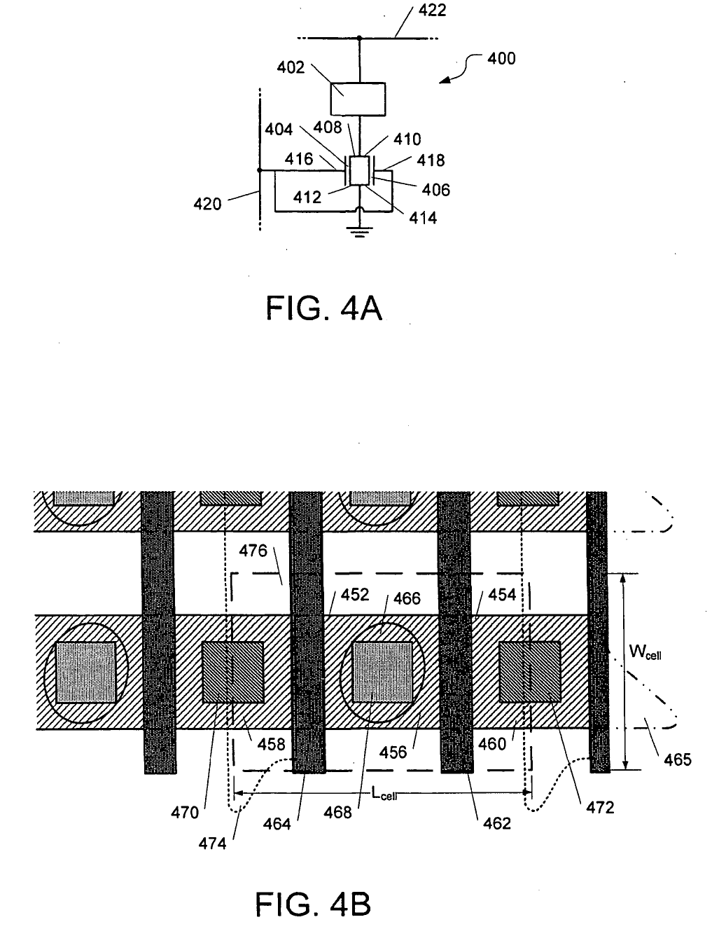

FIGS. 4A and 4B show an embodiment of a thermal select MRAM cell constructed in accordance with the principles of the present invention. In FIG. 4A, a block diagram of a memory cell 400 is shown. The memory cell 400 includes a magnetic tunnel junction (MTJ) 402, electrically connected in series with transistors 404 and 406, which are connected in parallel. Source portions 408 and 410 of transistors 404 and 406 are connected to the MTJ 402, and drain portions 412 and 414 are connected to ground. Gate portions 416 and 418 of the transistors 404 and 406 are connected to a word line 420. A bit line 422 is electrically connected to the MTJ 402. When the memory cell 400 is selected, a voltage on the word line 420 is applied to the gate portions 416 and 418 of the transistors 404, and 406 permitting current to flow from the bit line 422, through the MTJ 402 and the transistors 404 and 406. This current flow causes the heating of the MTJ 402, which permits a value to be written to the memory cell 400.

FIG. 4B shows an example layout for a thermal select MRAM memory cell in accordance with an embodiment of the present invention, such as is shown as a block diagram in FIG. 4A. As before, for purposes of illustration, a 65 nm CMOS technology is used.

A memory cell 450 includes transistors 452 and 454, having a common source region 456, drain regions 458 and 460, and gates 462 and 464. A bit line 465, in a metalization layer, is electrically connected to a magnetic tunnel junction (MTJ) 466, which is connected through a self-aligned via connection 468 to the common source region 456 of the transistors 452 and 454.

The drain region 458 of the transistor 452 is electrically connected to a metal ground line (not shown) through a self-aligned ground via connection 470. Similarly, the drain region 460 of the transistor 454 is connected to a metal ground line (not shown) through a self-aligned ground via connection 472.

A word line 474 is electrically connected to gates 462 and 464 of transistors 452 and 454, so that a current may flow through the MTJ 466 when an activation voltage is applied on the word line 474. An isolation region 476 isolates rows of cells from adjacent rows of cells in the word line direction. The symmetric design of the cells, using two transistors per cell, permits the isolation regions between adjacent cells in the bit line direction to be eliminated, improving the memory cell density.

Use of two transistors in parallel, as shown in FIG. 4B, permits a higher current to be driven through the common MTJ, despite a reduced width for the memory cell. For the memory cell shown in FIG. 4B, in a 65 nm CMOS technology, the width of the cell, W_{cell}, is 165 nm. The length of the cell, L_{cell}, is 250 nm. In terms of the minimum feature size, F, of 65 nm, W_{cell} is approximately 2.54 F and L_{cell} is approximately 3.85 F. This gives an overall cell area of approximately 9.76 F². Since the size of the cell is less than 10 F², the density of the memory cells should be competitive with other memory technologies.

To determine the transistor width, the width of the isolation area is subtracted from the overall cell width. Generally, the width of the isolation area is IF, or 65 nm in the case of the example described above. This means that the transistor width is only 100 nm. However, because there are two transistors, the effective transistor width for the cell is 200 nm. This is greater than the minimum transistor width of 170 nm that was computed above for a write current of 65 μA and a barrier resistance of 3.5 KΩ. Thus, the two-transistor design shown in FIG. 4B should be able to drive the required write current for a thermal select MRAM cell.

Generally, by using two transistors, the total effective transistor width for the cell is increased, while maintaining or reducing the actual width of the active area of the cell. The effective transistor width is related to the gate width within the active area of the cell, where the gate width is the gate dimension taken perpendicular to current flow through the transistor. Based on this, as will be seen below, other designs that increase gate width, and thus increase the effective transistor width within the active area of a cell may be used in accordance with the invention.

Additionally, because of the full symmetry of the cell layout of the two-transistor design shown in FIG. 4B, the isolation region between cells in the bit line direction can be removed. Elimination of the corner region of the active area of the cell, that needed to be surrounded by trench isolation, results in substantial improvement in printing, photolithographic tolerance, and reduced susceptibility to misalignment, particularly at the deep sub-micron integration scale. This fully symmetric layout results in an improved ability to manufacture memory devices, when compared with conventional asymmetric layouts.

A further benefit of the layout shown in FIG. 4B is that the two transistors in parallel can facilitate the formation of via contacts in a self-aligned manner, using the gate poly sidewall spacers. As can be seen in FIG. 4B, each via connection is placed between two gates, the sidewall spacers of which may be used to align the via contacts. Advantageously, such self-aligned contacts may be smaller than other via contacts, since it is not necessary to provide extra space to allow for misalignment.

It will be understood by one skilled in the relevant arts that the layout shown in FIG. 4B is for illustrative purposes, and that a similar two-transistor design may be used in other types of memory devices. For example, a similar design could be used to reduce the size of a spin-injection MRAM device or a PCRAM device. It will further be understood that, in accordance with the invention, similar designs may be employed in a variety of applications where high current and high density and/or small cell size are desirable. For example, a similar design can be used for diodes, power transistors, LCD applications, or a variety of non-volatile memory applications.

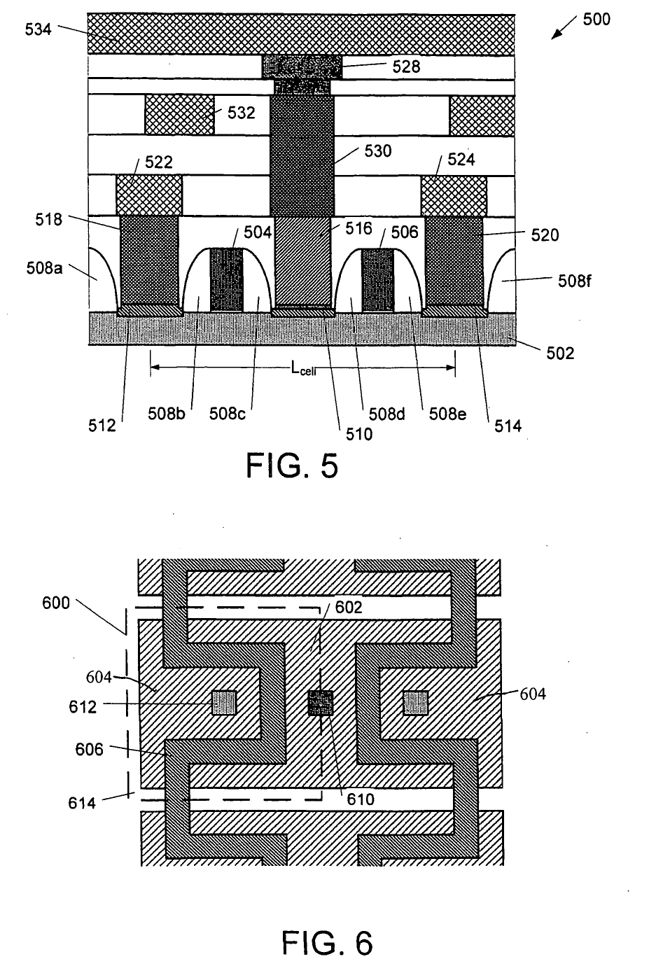

FIG. 5 shows a cross section of the memory cell design of FIG. 4B, illustrating the self-aligned via contacts of the two-transistor design. It should be noted that not all layers or connections are shown in FIG. 5, and there may be other layers or connections in the memory cell.

Cross-section 500 shows a substrate 502 that supports transistor gates 504 and 506, each of which defines a transistor. The gates 504 and 506, as well as adjacent gates on each side of the memory cell, include sidewall spacers 508a-508f. These sidewall spacers permit self-aligned contacts, including source contact 510 and drain contacts 512 and 514, and vias, including source via connection 516, and ground via connections 518 and 520. The ground via connections 518 and 520 are electrically connected to metal ground lines 522 and 524 in a first metalization layer. The source via connection 516 is connected to an MTJ 528 through a deep via connection 530. A metal word line 532 lies in a second metalization layer, and is connected to the gates 504 and 506 (connection not shown). The MTJ 528 is electrically connected to a metal bit line 534 in a third metalization layer.

It will be understood that other designs in which multiple transistors are used to increase the effective transistor width may also be employed to provide higher current in a reduced memory cell size in accordance with embodiments of the invention. For example, in some embodiments, multiple transistors may surround a magnetic junction element to provide higher current. In general, multiple transistors may be symmetrically arranged in parallel around a main electrical contact to an electrical element driven by a high current at the center of a cell. Asymmetric arrangements of multiple transistors may also be used in some embodiments.

In addition to using multiple transistors, a single transistor design, in which the transistor is modified to increase the effective transistor width to drive higher current may also be used in accordance with embodiments of the invention. Once such design is illustrated in FIG. 6.

FIG. 6 shows a single transistor design, using a “zig-zag” layout of the transistor to increase the effective transistor width. In the embodiment shown in FIG. 6, a memory cell 600 comprises a transistor having a source region 602, drain region 604, and gate 606. An MTJ (not shown) is connected to the source region 602 through a via connection 610. The drain region 604 is connected to ground through a ground via connection 612. An isolation region 614 separates the cell 600 from adjacent cells.

The drain region 604 is shared with an adjacent cell, permitting an increase in cell density. Additionally, because the via connection 610 and ground via connection 612 lie between portions of gates, the gate sidewalls may be used for self-alignment of these connections.

As can be seen, the gate 606 surrounds the ground via connection 612 on three sides, forming a “zig-zag” pattern, in which two parallel segments of the gate surround two sides of the ground via connection 612, and a third segment, which is perpendicular to the other two, covers a third side of the ground via connection 612. Using this arrangement, the effective width of the transistor is the total width of the gate 606 that lies within the active area of the cell 600. Thus, the effective width of the transistor, for purposes of driving current, is approximately three times the width of the cell. Thus, use of such a design permits a relatively narrow cell to drive sufficient current for use with a thermal select MRAM device or PCRAM device.

While the invention has been shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes that come within the meaning and range of equivalency of the claims are intended to be embraced.

What is claimed is:

1. A method of producing a cell in an active area of a semiconductor device, the active area having a length and a width, the method comprising:
providing a transistor in the active area, the transistor including a gate that separates a source region of the transistor from a drain region of the transistor in the active area of the cell, the source region being coupled to a memory cell and the drain region being coupled to a reference voltage potential;
wherein an effective width of the transistor is greater than the width of the active area of the cell.

2. The method of claim 1, wherein the transistor comprises a first transistor and a second transistor electrically connected in parallel with each other between the memory cell and the reference voltage potential, such that the effective width of the transistor is the sum of the effective width of the first transistor and the effective width of the second transistor.

3. The method of claim 2, wherein the effective width of the first transistor and the effective width of the second transistor are each equal to the width of the active area of the cell, such that the effective width of the transistor is twice the width of the active area of the cell.

4. The method of claim 1, wherein the gate includes at least three segments, wherein two of the segments of the gate are parallel to each other, and the third segment is perpendicular to the other two segments, and wherein the sum of the effective widths of the segments is greater than the width of the active area of the cell.

5. The method of claim 4, wherein the effective width of the transistor is approximately three times the width of the active area of the cell.

6. A cell in a semiconductor device, the cell comprising:
a transistor, including a gate, a source region, and a drain region in an active area of the cell, the active area having a length and a width, wherein an effective width of the transistor is greater than the width of the active area of the cell because a total width of the gate is greater than the width of a single gate that extends in a straight line along the width of the active area of the cell.

7. The cell of claim 6, further comprising a second transistor electrically connected in parallel with the transistor, such that the effective width is the sum of the width of the gate of the transistor and the width of the gate of the second transistor.

8. The cell of claim 7, wherein the width of the gate of the transistor and the width of the gate of the second transistor are each equal to the width of the active area of the cell, such that the effective width of the transistor is twice the width of the active area of the cell.

9. The cell of claim 6, wherein the gate of the transistor includes at least three segments, wherein two of the segments are parallel to each other, and the third segment is perpendicular to the other two segments, and wherein the sum of the lengths of the segments is greater than the width of the active area of the cell.

10. The cell of claim 6, wherein the semiconductor device comprises an MRAM device, and wherein the cell further comprises a magnetic tunnel junction that is electrically connected to the source region of the transistor.

11. A cell in a semiconductor device comprising a plurality of cells, the cell comprising:
a first transistor having a first drain region and a first gate that includes sidewall spacers;
a second transistor having a second drain region and a second gate that includes sidewall spacers;
a common source region shared by the first and second transistors, such that the first and second transistors are electrically connected in parallel with each other;
a via connection electrically connected to the common source region;
a first ground via connection, electrically connecting the first drain region to ground; and
a second ground via connection electrically connecting the second drain region to ground.

12. The cell of claim 11, wherein the via connection is self-aligned between sidewall spacers of the first gate and the second gate.

13. The cell of claim 11, wherein the first ground via connection is self-aligned between a sidewall spacer of the first gate and a sidewall spacer of a gate of a transistor on an adjacent cell, and the second ground via connection is self-aligned between a sidewall spacer of the second gate and a sidewall spacer of a gate of a transistor on a second adjacent cell.

14. The cell of claim 1 1, wherein the first drain region is shared between the first transistor and a transistor on a first adjacent cell, and the second drain region is shared between the second transistor and a transistor on a second adjacent cell.

15. The cell of claim 11, wherein the semiconductor device comprises an MRAM device, and wherein the cell further comprises a magnetic tunnel junction electrically connected to the common source region through the via connection.

16. The cell of claim 15, further comprising a bit line electrically connected to the magnetic tunnel junction.

17. The cell of claim 16, further comprising a word line electrically connected to the first gate and the second gate.

18. The cell of claim 15, wherein the MRAM device comprises a thermal select MRAM device.

19. The cell of claim 15, wherein the MRAM device comprises a spin injection MRAM device.

20. The cell of claim 11, wherein the semiconductor device comprises a PCRAM device.
